(19) United States
(12) Patent Application Publication
(10) Pub. No.: US 2014/0302631 A1
(43) Pub. Date: Oct. 9, 2014

(54) Sensor

(71) Applicant: Nokia Corporation, Espoo (FI)

(72) Inventors: Marko J. Eromaki, Tampere (FI); Mikko Antti Ollila, Tampere (FI)

(21) Appl. No.: 14/307,910

(22) Filed: Jun. 18, 2014

Related U.S. Application Data
(62) Division of application No. 13/703,462, filed on Feb. 27, 2013.

(51) Int. Cl. H01L 31/0203; H01L 27/146

(52) U.S. Cl. CPC H01L 31/0203; H01L 27/14685
USPC 438/64

(57) ABSTRACT

A method including encapsulating, at least partially, a transparent substrate supporting a sensor, in a casing. The casing includes interconnects to the sensor.

### CROSS REFERENCE TO RELATED APPLICATION

This is a divisional patent application of copending application Ser. No. 13/703,462 filed Feb. 27, 2013, which is a national stage application of International Application No. PCT/IB2010/052772, filed Jun. 18, 2010, which are hereby incorporated by reference in their entireties.

### TECHNOLOGICAL FIELD

Embodiments of the present invention relate to a sensor. In particular, they relate to packaging an image sensor in a module.

### BACKGROUND

Currently image sensors are typically surface mounted on top of a printed wiring board substrate to create a module that may be integrated within an electronic device.

### BRIEF SUMMARY

According to various, but not necessarily all, embodiments of the invention there is provided an apparatus comprising: a transparent substrate comprising a first surface and an opposing second surface; a sensor connected to the first surface of the transparent substrate; and a casing, comprising interconnects to the sensor, and defining a cavity and at least one aperture to the cavity, wherein the transparent substrate and the sensor are located within the cavity with the second surface of the transparent substrate adjacent the at least one aperture.

According to various, but not necessarily all, embodiments of the invention there is provided a method comprising: encapsulating, at least partially, a transparent substrate supporting a sensor, in a casing comprising interconnects to the sensor.

### BRIEF DESCRIPTION

For a better understanding of various examples of embodiments of the present invention reference will now be made by way of example only to the accompanying drawings in which:

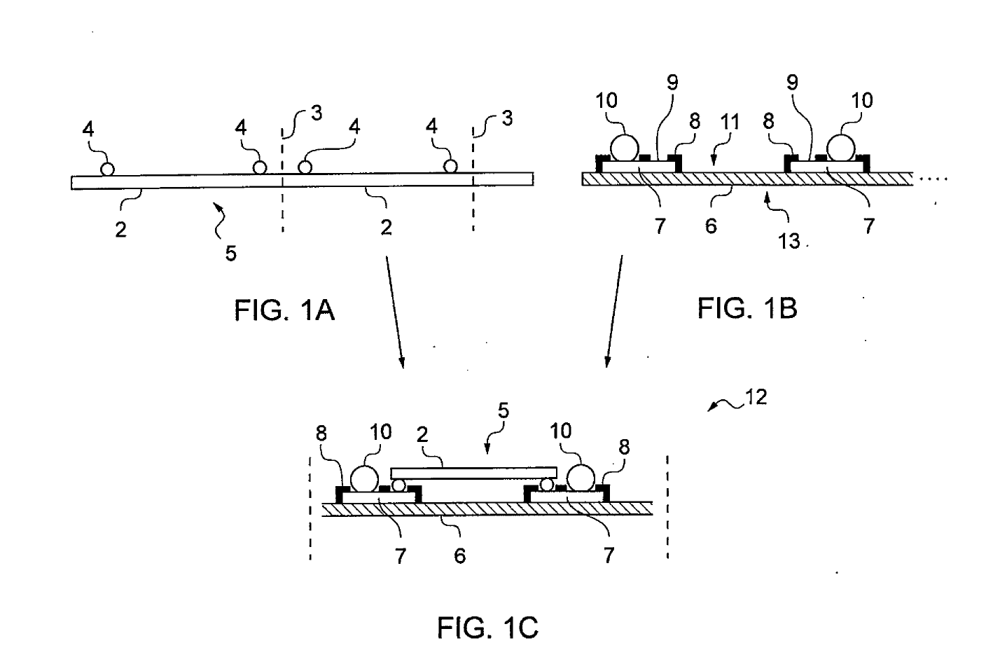

FIG. 1A schematically illustrates a flip chip component comprising a sensor;

FIG. 1B schematically illustrates an intermediate component;

FIG. 1C schematically illustrates the combination of the flip chip component and the intermediate component to form a chip-scale component;

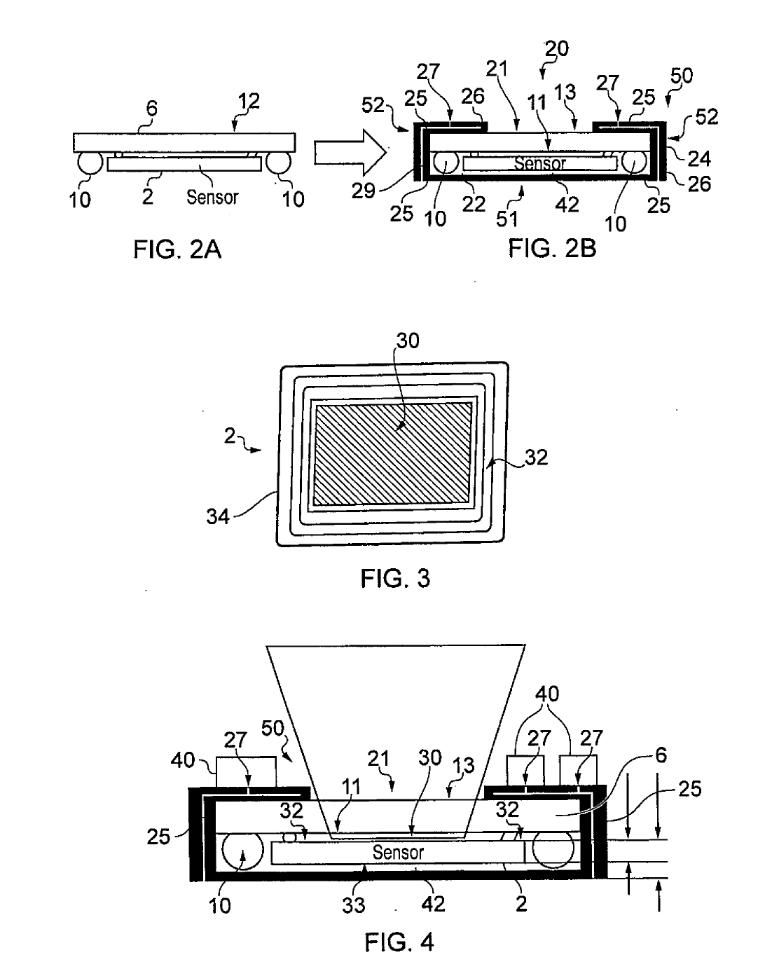

FIG. 2A schematically illustrates the chip-scale component before packaging;

FIG. 2B schematically illustrates the chip-scale package comprising the chip scale component;

FIG. 3 schematically illustrates a plan view of one example of a sensor;

FIG. 4 schematically illustrates a chip-scale package comprising surface mounted electrical components;

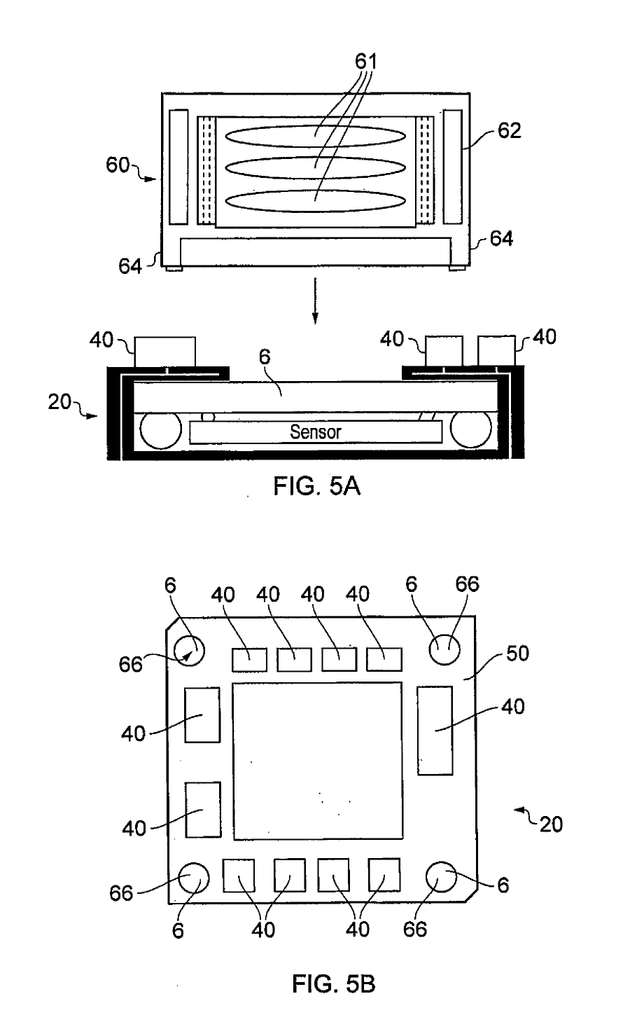

FIG. 5A schematically illustrates in side view how an optical component may be secured to the chip-scale package; and

FIG. 5B illustrates chip-scale package in plan view before the optical component is secured.

### DETAILED DESCRIPTION

Referring to FIGS. 2B and 4, there is illustrated an apparatus 20 comprising: a transparent substrate 6 comprising a first surface 11 and an opposing second surface 13; a sensor 2 connected to the first surface 11 of the transparent substrate 6; and a casing 24, comprising interconnects to the sensor 2, and defining a cavity 22 and at least one aperture 21 to the cavity 22, wherein the transparent substrate 6 and the sensor 2 are located within the cavity 22 with the second surface 13 of the transparent substrate 6 adjacent the at least one aperture 21.

FIG. 1A schematically illustrates manufacturing of components 5 by making cuts 3. Each component 5 comprises a sensor 2 having a plurality of connectors 4. The connectors 4 may be formed from a conductive material that can be melted in-situ such as solder. The connectors may be formed as a ball grid array (BGA). The component 5 may be a flip chip component.

The sensor 2 is in this example an optical or image sensor such as, for example, a color camera sensor. It may employ any suitable sensing technology.

FIG. 1B schematically illustrates an intermediate component used to form a chip-scale component 12 (FIG. 1C).

The intermediate component comprises a transparent substrate 6. The transparent substrate 6 is flat having parallel first and second surfaces 11, 13. A patterned conductive Interconnect 7 is formed on the first surface 11 of the transparent substrate 6. The opposing second surface 13 of the transparent substrate 6 is left clear.

A patterned passivation layer 8 is formed over the conductive interconnect 7 on the first surface 11. The patterning of the passivation layer 8 includes vias (openings) through the passivation layer 8 to expose the underlying conductive interconnect 7. Connectors 10 are formed in a first plurality of the vias. The connectors 10 may be formed from a conductive material that can be melted in in-situ such as solder. A second plurality of vias 9 are left exposed.

FIG. 1C schematically illustrates the combination of the flip chip component 5 and the intermediate component to form a chip-scale component 12. This chip-scale component will subsequently (FIGS. 2A and 2B) be packaged to form a chip-scale package 20.

The flip chip component 5 is flipped and bonded to the intermediate component. The connectors 4 of the flip chip 5 are aligned with the vias 9 and bonded (e.g. by soldering) to the conductive interconnect 7 through the vias 9.

FIG. 2A schematically illustrates the chip-scale component 12 before it is packaged to form an apparatus 20 which may be chip-scale package such as a camera module. The packaging process comprises the surface mounting of the chip-scale component 12.

Referring to FIG. 2B, the chip-scale component 12 is encapsulated, at least partially, in a casing 24 comprising interconnects to the sensor 2. The encapsulation forms a chip-scale package 20 in this example. The sensor 2 is the chip in the chip-scale package 20 which is surface mountable. The package 20 is only slightly (e.g. <50% by area) bigger than the chip.

The encapsulating casing 24 comprises one or more supports 29 for supporting patterned conductive interconnects 25 and protective material 26. The protective material typically overlies the conductive interconnects and some or all of the supports 29.

The chip-scale component 12 may be surface mounted on a portion of the casing 24 before the casing 24 is manufactured to encapsulate the chip-scale component 12. The connectors 10 of the chip-scale component 10 connect to the conductive interconnects 25 of the casing 24.

Vias 27 may be made through the protective material 26 of the casing 24 to at least some of the conductive interconnects 25. The technology used to form the interconnects 25, protective material 26 and vias 27 is very similar to that used to produce printed wiring boards (also called printed circuit boards). For example, the protective material 26 may, for example, be formed by curing resin-impregnated fabric. The casing 24 may therefore be considered to be a printed wiring board casing, where the printed wiring board defines a three-dimensional surface and encapsulates, at least partially, the chip-scale component 12.

The transparent substrate 6 is configured to protect the sensor 2 from thermal shock during formation of the casing 24.

An aperture 21 in the casing 24 may be created to expose the transparent substrate 6 and the underlying supported sensor 2. The aperture 21 may be formed by removing, by etching for example, a portion of the protective material 26 of the casing 24 that overlies the transparent substrate 6 while the transparent substrate 6 and sensor 2 are in situ. The transparent substrate 6 protects the sensor 2 as it is resistant to the processes used to remove a part of the casing 24 to form the aperture 21.

The apparatus 20 has in its front face 50 a portion of the casing 24 and a portion of the transparent substrate 6 exposed through the aperture 21. The casing 24 also extends around the side walls 52 and rear face 51 of the apparatus 20.

The casing 24 forms a cavity 22 that houses the sensor 2 suspended from the transparent substrate 6.

The cavity 22 has a depth that is greater than the depth of the chip-scale component 12. A gap 42, which is unoccupied, is formed between the inactive surface 33 of the sensor 2 and a rear wall of the casing 24. The gap is small so that the active surface 34 of the sensor 2, adjacent the transparent substrate 6, is positioned less than 0.3 mm from the back face 51 of the casing. The image plane of the sensor 2 is therefore as low as possible enabling the apparatus 20 to be low-profile or comprise additional optics (see FIGS. 5A, 5B)

The rigidity of the transparent substrate 6 provides rigidity to the apparatus 20. The transparent substrate 6 may have a coating, for example, an infrared filter coating or anti-reflective coating. The transparent substrate 6 may be formed from glass.

FIG. 3 schematically illustrates a plan view of one example of a sensor 2. In this example, the active surface 34 of the sensor 2 is illustrated. The active surface 34 comprises a central active area 30 and a surrounding peripheral non-active area 32 which may be used for logic circuitry for example.

Referring to FIG. 4, in this example, the sensor 2 illustrated in FIG. 3, or a similar sensor 2, is encapsulated in casing 24 as previously described with reference to FIG. 2B. The central active area 30 is aligned with and is substantially in register with the aperture 21. The surrounding peripheral non-active area 32 underlies portions of the casing 24 on the front face 50. Those portions have vias 27 to the underlying conductive interconnect 25. Electrical components 40 are mounted at these portions, on the front face 50, such that they make electrical connection to the underlying conductive interconnect 25 through the vias 27. Surface mounting techniques may be used to make these connections.

The electrical components 40 are mounted on the casing 24 overlying the non-active area 32 but not overlying the active area 30.

In FIG. 4, the transparent substrate 6 has a depth between the first surface 11 and the second surface 13 of, for example, 0.4 mm. The sensor 2 has a depth between its active surface 30 and inactive surface 33 of, for example, 100 μm

The separation between the active surface 30 of the sensor 2 and the rear face 51 of the casing 26 is, for example, less than 300 μm.

The second surface 13 of the transparent substrate 6 acts as a dust barrier and the separation of the second surface 13 from the active surface 30 of the sensor 2 obviates interference in the imaging by sensor 2 caused by dust on the second surface 13.

FIG. 5A schematically illustrates in side view how an optical component 60 may be secured to the apparatus 20, which is similar to the apparatus 20 illustrated in FIG. 4.

In this example, the optical component 60 is an opto-mechanical unit that comprises one or more lenses 61 and an actuator 62 for configuring the lens or lenses.

The optical component 60 has a number of legs 64 that extend downwards to support the optical component 60 on the front face 50 of the apparatus 20.

FIG. 5B illustrates the apparatus 20 in plan view. The front face 50 of the apparatus has apertures 66 in the casing 24, in three or four corners, that expose portions of the transparent substrate 6. The legs 64 of the optical component pass through the apertures 66 and rest directly on the flat second surface 13 of the transparent substrate 6. This creates a datum surface and enables very precise tolerances between the sensor 2 and the lens or lenses 61.

As used here ‘module’ refers to a unit or apparatus that excludes certain parts/components that would be added by an end manufacturer or a user.

Although embodiments of the present invention have been described in the preceding paragraphs with reference to various examples, it should be appreciated that modifications to the examples given can be made without departing from the scope of the invention as claimed.

Features described in the preceding description may be used in combinations other than the combinations explicitly described.

Although functions have been described with reference to certain features, those functions may be performable by other features whether described or not.

Although features have been described with reference to certain embodiments, those features may also be present in other embodiments whether described or not.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

What is claimed is:

1. A method comprising:
encapsulating, at least partially, a transparent substrate supporting a sensor, in a casing comprising interconnects to the sensor.

2. A method as claimed in claim 1, wherein the sensor has a central active area and a surrounding peripheral non-active area, wherein the active area is positioned adjacent an aperture in the casing and wherein a plurality of electrical components are mounted on the casing overlying the non-active area but not overlying the active area.

3. A method as claimed in claim 1, wherein the transparent substrate is configured to protect the sensor from thermal shock during formation of the casing.

4. A method as claimed in claim 1, wherein an aperture in the casing to expose the transparent substrate and supported sensor is formed by removing a portion of the casing that overlies the transparent substrate, wherein the transparent substrate protects the sensor.

5. A method as claimed in claim 4, wherein the transparent substrate is resistant to the processes used to remove a part of the casing to form the aperture.

6. A method as claimed in claim 1, wherein the encapsulating casing is formed as a printed wiring board casing comprising a support, conductive interconnects supported by the support and protective material overlying at least an exterior portion of the support, the method further comprising forming vias through the protective material to at least some of the conductive interconnects.

7. A method as claimed in claim 1, comprising forming the casing by curing resin-impregnated fabric.

8. A method as claimed in claim 1, comprising surface mounting the transparent substrate supporting the sensor.

9. A method as claimed in claim 1, comprising surface mounting the transparent substrate supporting the sensor, by creating solder contacts between interconnects on the first surface of the transparent substrate that interconnect the sensor and electrical interconnects of the casing.
